(19) United States
(12) Patent Application Publication
(10) Pub. No.: US 2013/0037929 A1
(43) Pub. Date: Feb. 14, 2013

(54) STACKABLE WAFER LEVEL PACKAGES AND RELATED METHODS

(71) Applicants: Kay S. Essig, Leipzig (DE); Bernd K. Appelt, Gulf Breeze, FL (US)

(72) Inventors: Kay S. Essig, Leipzig (DE); Bernd K. Appelt, Gulf Breeze, FL (US)

(21) Appl. No.: 13/206,346

(22) Filed: Aug. 9, 2011

(51) Int. Cl. H01L 23/48; H01L 21/56

(52) U.S. Cl. 257/693; 438/124; 257/E23.01; 257/E21.502

(57) ABSTRACT

The present semiconductor device packages include a die, a redistribution layer and a plurality of conductive pillars electrically connected to the redistribution layer. A molding compound partially encapsulates the die and the pillars. A plurality of interconnect patterns on the molding compound are electrically connected to the pillars. The interconnect patterns provide electrical connections for a second, stacked semiconductor package.

### TECHNICAL FIELD

The present disclosure relates to semiconductors and more particularly to semiconductor assembly and packaging.

### BACKGROUND

Wafer-level packaging (WLP) is advantageous because it significantly improves packaging efficiency and reduces the size of semiconductor packages. Conventional fan-in WLP processes are performed on an uncut wafer, leading to the final packaged product being the same size as the die itself. Conventional fan-out WLP processes start with a reconstituted wafer (reconfiguration of individual dies into an artificial molded wafer), and can eliminate the need for expensive flip-chip substrates by expanding the package size with the mold compound for higher I/O applications.

For three-dimensional wafer level packaging (3-D-WLP), efficient and reliable electrical connections between stacked elements are desirable.

### SUMMARY

One of the present embodiments comprises a semiconductor device package. The package comprises a die having an active surface. The package further comprises a molding compound partially encapsulating the die and has an upper surface. The package further comprises a redistribution layer including at least one conductive layer and at least one dielectric layer. The redistribution layer is formed partially on the active surface and partially on a lower surface of the molding compound. The package further comprises a plurality of conductive pillars disposed in the molding compound and electrically connected to the redistribution layer. The package further comprises a plurality of recesses in the upper surface of the molding compound. Locations of the recesses correspond to locations of the conductive pillars. The package further comprises a plurality of interconnect patterns electrically connected to the pillars. At least one of the interconnect patterns extends into at least one of the recesses.

Another of the present embodiments comprises a semiconductor device package. The package comprises a die having an active surface. The package further comprises a molding compound partially encapsulating the die and having an upper surface. The package further comprises a redistribution layer including at least one conductive layer and at least one dielectric layer. The redistribution layer is formed partially on the active surface and partially on a lower surface of the molding compound. The package further comprises a plurality of conductive pillars disposed in the molding compound and electrically connected to the redistribution layer. The package further comprises a plurality of recesses in the upper surface of the molding compound. Locations of the recesses correspond to locations of the conductive pillars and exposing at least a portion of upper surfaces of the pillars. The molding compound overlaps edges of the upper surfaces of the pillars.

Another of the present embodiments comprises a method of making a semiconductor device package. The method comprises forming a plurality of conductive pillars on a sacrificial layer. The method further comprises placing at least one die on the sacrificial layer. The method further comprises forming a molding compound on the sacrificial layer and encapsulating the at least one die and at least the partially encapsulating the pillars. The method further comprises forming a plurality of recesses in the molding compound adjacent upper surfaces of the pillars. The method further comprises forming a plurality of interconnect patterns on the molding compound and the pillars. The interconnect patterns at least partially fill the recesses in the molding compound. The method further comprises removing the sacrificial layer. The method further comprises forming a redistribution layer on the die, the pillars and the molding compound. The redistribution layer includes at least one conductive layer and at least one dielectric layer.

### BRIEF DESCRIPTION OF THE DRAWINGS

FIG. 1 is a schematic cross-sectional view of a wafer level package structure according to one of the present embodiments;

FIG. 2A is a schematic cross-sectional view of a stacked package structure according to one of the present embodiments;

FIG. 2B is a schematic cross-sectional view of a stacked package structure according to another of the present embodiments;

FIGS. 3A-3H illustrate a manufacturing process for a stackable wafer level package structure according to one of the present embodiments;

FIGS. 4A-4G illustrate a manufacturing process for a stackable wafer level package structure according to another of the present embodiments;

FIGS. 5A-5G illustrate a manufacturing process for a stackable wafer level package structure according to another of the present embodiments;

FIGS. 6A-6F illustrate a manufacturing process for a stackable wafer level package structure according to another of the present embodiments; and

FIGS. 7A-7E illustrate a manufacturing process for a stackable wafer level package structure according to another of the present embodiments.

Common reference numerals are used throughout the drawings and the detailed description to indicate the same elements. The present invention will be more apparent from the following detailed description taken in conjunction with the accompanying drawings.

### DETAILED DESCRIPTION

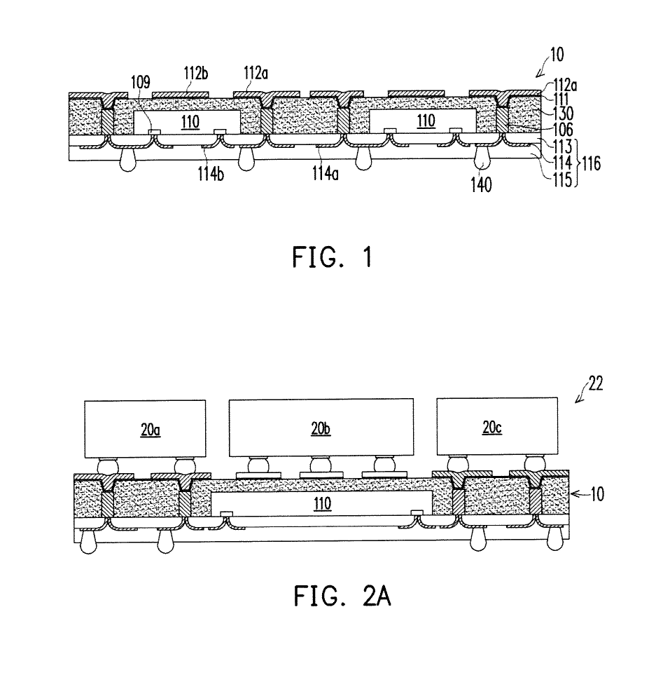

Referring to FIG. 1, a wafer-level package (WLP) 10 according to one of the present embodiments is illustrated. The package 10 includes chips 110 (also referred to as die), a molding compound 130 encapsulating the chips 110, a plurality of pillars 106 embedded within the molding compound 130, interconnect patterns 112a connecting the pillars 106 to trace patterns 112b, and a redistribution layer 116. The redistribution layer 116 includes a first dielectric layer 113, a conductive layer 114, and a second dielectric layer 115. In alternative embodiments the redistribution layer 116 may be a single layer (with only the conductive layer 114).

The package 10 may further include a seed layer 111 located between the interconnect patterns 112a and the molding compound 130, between the interconnect patterns 112a and the pillars 106, and between the trace patterns 112b and the molding compound 130. The interconnect patterns 112a may be used for stacking another semiconductor package or another electronic component on the package 10, as further described below.

In addition, the package 10 may further include electrical contacts 140 located on the conductive layer 114 of the redistribution layer 116. Electrical contacts 140 may be used for connecting the package 10 to an external component, such as a system level circuit board (not shown). The conductive layer 114 electrically connects one of the contacts 109 of the chip 110 and one of the electrical contacts 140, or electrically connects one of the pillars 106 and one of the electrical contacts 140. Bottom conductive layer 114 is patterned into bottom interconnect patterns 114a that are electrically connected to the pillars 106, and bottom trace patterns 114b. The chip 110 may be an integrated circuit or other type of semiconductor die, such as a micro electro-mechanical system (MEMS). While the package 10 illustrated in FIG. 1 contains two semiconductor chips 110, a wafer level package according to the present embodiments can include any number of semiconductor chips, including only one or more than three.

In the illustrated embodiment, the pillars 106 are cylindrical. However, in other embodiments the pillars 106 may have other shapes, such as conical. The pillars 106 can be any conductive material, such as copper. Solid copper pillars provide superior conductivity compared to plated vias, for example. One advantage of forming the pillars 106 that are subsequently encapsulated with mold compound 130 and then connected to interconnect patterns 112a is that the aspect ratio, i.e. the hole depth/hole diameter, of the pillars 106 is decreased. Lower aspect ratios improve the probability of pillars without voids or other anomalies and thus result in higher reliability interconnects.

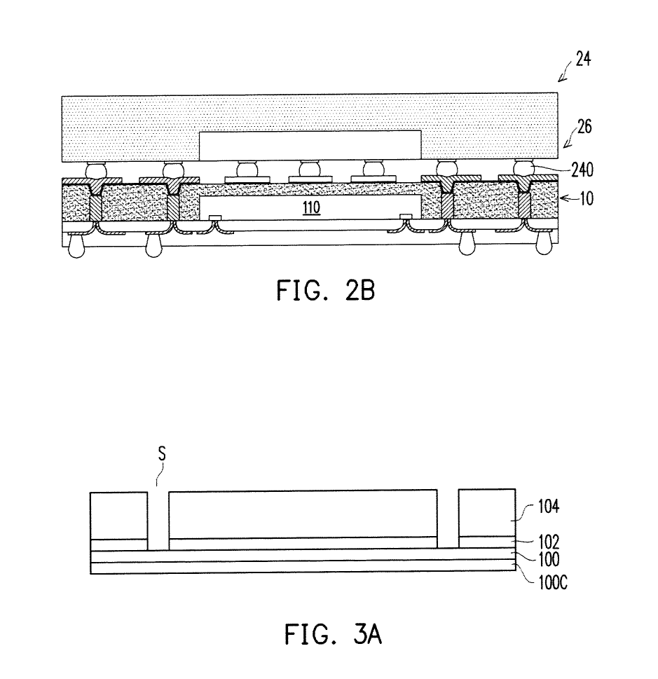

FIG. 2A illustrates a stacked package structure 22 according to one of the present embodiments. The structure 22 includes a plurality of electronic components 20a, 20b and 20c stacked on the above-described package 10. The components 20a, 20b and 20c may be, for example, dies, packages, passive devices, or any other components, and may be mounted on the package 10 by, for example, flip chip technology, surface mount technology, or any other type of attachment technique.

FIG. 2B illustrates another stacked package structure 24 according to another of the present embodiments. The structure 24 includes a package structure 26 stacked on the above-described package 10. The package structure 26 is electrically connected to the package structure 10 through a plurality of electrical contacts 240. In the illustrated embodiment, the package structure 26 may be another wafer level package having a fan-out redistribution layer (RDL) (not shown) on a lower surface, which then is electrically connected to an upper surface of the package 10.

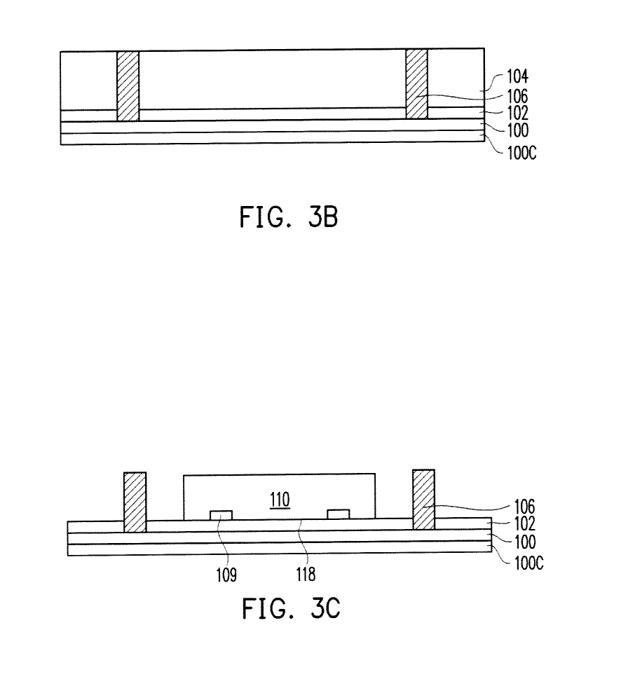

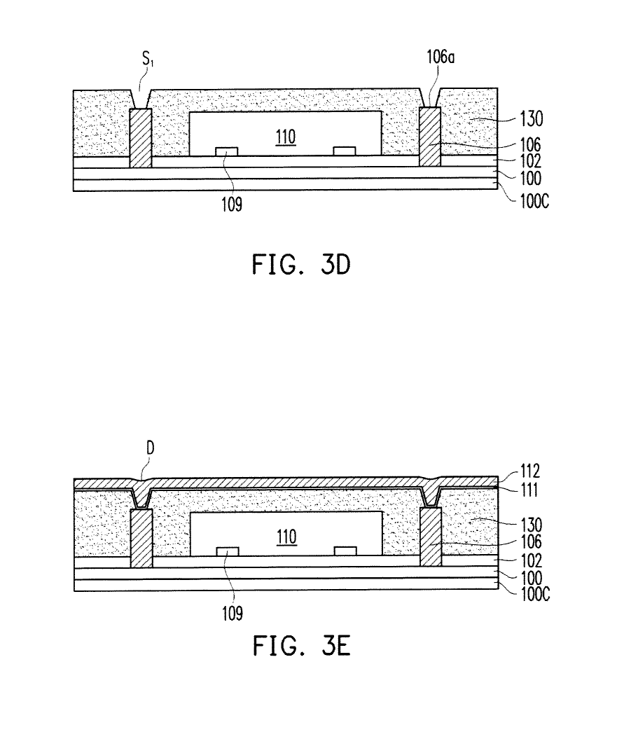

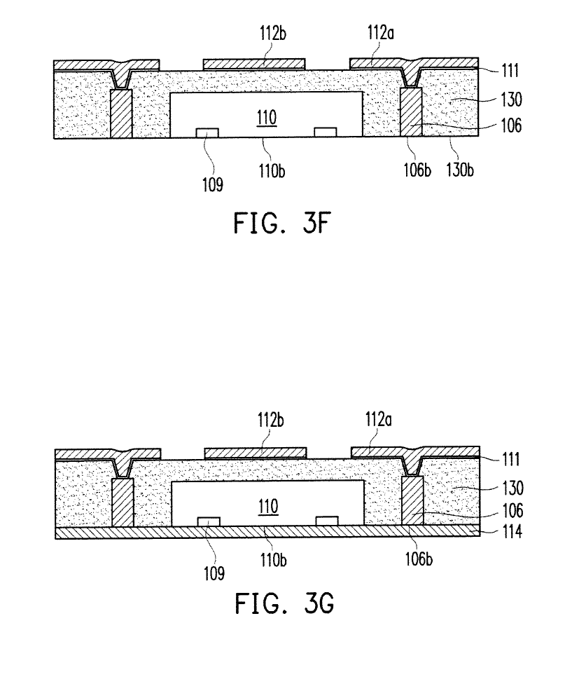

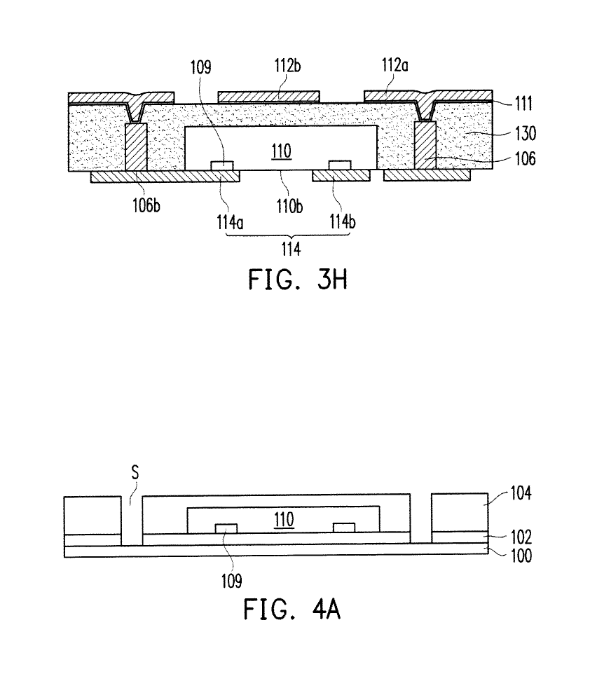

FIGS. 3A-3H illustrate a manufacturing process of a wafer level package structure according to one of the present embodiments. With reference to FIG. 3A, a sacrificial layer 100 having a tape 102 covering the top surface thereof, and a photoresist layer 104 covering the tape 102 is formed. The sacrificial layer 100, the tape 102 and the photoresist layer 104 are supported on a rigid carrier 100C. A plurality of openings S are formed in the tape 102 and the photoresist layer 104. The openings S may be formed by UV laser drilling, carbon dioxide laser drilling, or any other technique. The sacrificial layer 100 may be a metal such as copper (Cu) foil, or any other metal. The tape 102 may be a die-bonding tape, for example, or another type of tape. The photoresist layer 104 may be a dry film resist layer, for example, or another type of photoresist layer.

Referring to FIG. 3B, a plurality of pillars 106 is formed in the openings S. The pillars 106 may be formed by plating, or by any other process. In certain embodiments, the pillars 106 may be a metal, such as copper, and may be formed by pattern plating, for example. In certain embodiments, the sacrificial layer 100 may be used as a cathode, such that the pillars 106 can be electroplated into the openings S.

Referring to FIG. 3C, after removing the photoresist layer 104, at least one chip or die 110 is bonded face down to the tape 102. The die 110 includes at least one contact pad 109 on its downward facing (i.e. active) surface 118. The die 110 is preferably a known good die (KGD) picked from an original wafer after testing. The die 110 may be I/O pad limited, and therefore require fanning out to accommodate larger external interconnects like solder balls. Alternatively, the die 110 may not be pad limited where the end application desires a 3-D package. Dies will not be placed in the sites where plating deficiencies in the pillars are found, as plating deficiencies may result in sub-optimal electrical connections. Optical inspection may reveal missing, incomplete or imperfect plating of the pillars 106. By placing good dies with good pillars, package yield is thereby increased.

Referring to the FIG. 3D, the sacrificial layer 100 and the die 110 mounted thereon are over molded with a molding compound 130 covering the die 110, the pillars 106, the tape 102, and the sacrificial layer 100. The over molding may comprise a compression molding process, which has been found to reduce or eliminate the incidence of voids in the molding compound 130.

A plurality of recesses S₁ are formed by removing portions of the molding compound 130 such that upper surfaces 106a of the pillars 106 are exposed. The removal process may be performed by UV laser drilling, carbon dioxide laser drilling or any other process. In the illustrated embodiment, the recesses S₁ are tapered or conical, with a top aperture 121 being larger than a bottom aperture 123. In alternative embodiments, the recesses S₁ may be non-tapering and/or of a slightly smaller diameter than the pillars 106 to avoid forming a gap between the pillars 106 and the mold compound 130.

With continued reference to FIG. 3D, the mold compound 130 overlaps edges of the upper surfaces 106a of the pillars 106. The recesses S₁ are conical, with a larger diameter spaced from the upper surfaces 106a of the pillars 106 and a smaller diameter adjacent the upper surfaces 106a of the pillars 106. This shape and the overlap between the mold compound 130 and the edges of the upper surfaces 106a, results from a laser drilling process in forming the recesses S₁. If the laser is not properly registered over the pillar 106, it could remove portions of the mold compound 130 adjacent to side surfaces of the pillar 106, which is undesirable. Forming the recesses S₁ with the illustrated configuration reduces the likelihood of that undesirable outcome. Alternatively, the mold compound 130 may be ground down to expose the upper surfaces 106a.

Referring to FIG. 3E, a seed layer 111 is applied to the upper surface of the molding compound 130, and into the recesses S₁ to cover the upper surfaces 106a of the pillars 106. The seed layer 111 may be applied by sputtering, for example, or by any other process. The seed layer 111 may be any material, and may have multiple layers. For example, the seed layer 111 may have a tungsten layer covered by a layer of copper, or nickel or chromium. Then, a conductive layer 112 is formed on the seed layer 111 and is thus electrically connected with the pillars 106. The conductive layer 112 may be a metal, such as copper and its alloys, or any other metal. The conductive layer 112 may formed by plating, for example, or by any other process.

In general, depending on the aspect ratio of the recesses S1, the conductive layer 112 may partially or completely fill the recesses S₁. Preferably, the conductive layer 112 plates the sidewalls of the recesses S₁ and electrically connects to the pillars 106. A conductive layer 112A depression or indentation D may be present above the pillars 106. The conductive layer 112 located within each recess S₁ functions as a via to route a signal from a lower surface of the package to an upper surface of the package conductive layer 112.

Referring to FIG. 3F, the conductive layer 112 is patterned to form a routing layer or trace pattern 112b on the upper surface of the package, as well as interconnect patterns 112a, which are electrically connected to the pillars 106. The patterns may be defined by subtractive etching, for example, or by any other process. Subsequent to patterning the conductive layer 112, the carrier 100C (FIG. 3E) is removed. Then, the sacrificial layer 100 at the bottom is removed and a portion of the pillars 106 are removed until the bottom surfaces 106b of the pillars 106 are substantially co-planar with the bottom surface 110b of the die 110. The removal processes may comprise etching, for example, or any other process. Alternatively, the pillars 106 may be removed until the bottom surfaces 106b of the pillars 106 are slightly concave or convex from the bottom surface 130b of the molding compound. Then, the tape 102 is removed to expose the pillars 106 and the bottom surface 110b of the die 110. The contact pads 109 are exposed.

In another embodiment, the sacrificial layer 100 may be selectively removed, so that the sacrificial layer 100 adjacent to the pillars 106 is removed until the bottom surfaces 106b of the pillars 106 are substantially co-planar with or slightly concave or convex from the bottom surface 130b of the molding compound. Thereafter, the tape 102 is removed together with the remaining sacrificial layer 100 to expose the pillars 106 and the bottom surface 110b of the die 110.

Referring to FIG. 3G, a bottom conductive layer 114 is formed to cover the bottom surface 110b of the die 110 and the pillars 106, which may be subject to a cleaning process. The bottom conductive layer 114 may be a metal, such as copper or a copper alloy, for example, or any other material. In this embodiment, the contact pads 109 of the die 110 may be copper pads that are sufficiently thick to be compatible with cleaning and metallization processes.

Referring to FIG. 3H, the bottom conductive layer 114 is patterned into bottom interconnect patterns 114a that are electrically connected to the pillars 106, and bottom trace patterns 114b. The upper conductive layer 112 and the bottom conductive layer 114 may be patterned at the same time by double sided processing, or patterned in sequential steps. The trace patterns 112b, 114b may be the same or different, depending on the product design. The locations of the interconnect patterns 112a, 114a correspond to the locations of the pillars 106. However, the arrangement or the design of the patterns should be adjusted according to the chip(s) or device(s) included in the package.

An anti-tarnish layer or a finish layer, such as a nickel/gold layer, organic solderabilty preservatives (OSP), electroless nickel-immersion gold (ENIG), or electroless nickel/electroless palladium/immersion gold (ENEPIG), may be formed over the upper and lower patterned layers 112, 114 to enhance additional connections. Furthermore, a protective dielectric layer, such as a solder mask, may be applied over the upper and lower patterned layers 112, 114 such that only predetermined ball pads are exposed for mounting solder balls.

In the above embodiment, as in all embodiments described herein, the pillars may be plated in a single step on a copper foil using pattern plating. The foil can be in panel (rectangular) matrix format. In one example, two or three wafers can be plated at once and then later transferred to a suitable carrier. Display panels, which are several times larger than printed wiring board (PWB) panels. These panels can hold wafers, which increases the pillar plating efficiency significantly. If plated in panel format, two foils can be plated at the same time by mounting two foils on a single carrier, thereby improving manufacturing efficiency.

In the sequential step process described above for forming the pillars 106 and the conductive layer 112, the pillar height may advantageously be designed to any reasonable height, and does not expose the die 110 or the mold compound 130 to plating chemistry (in the case of a plating process), which could attack the other elements.

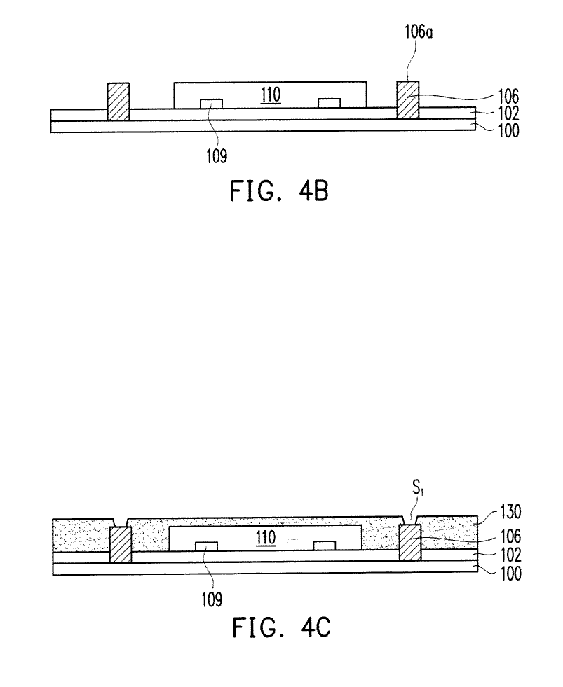

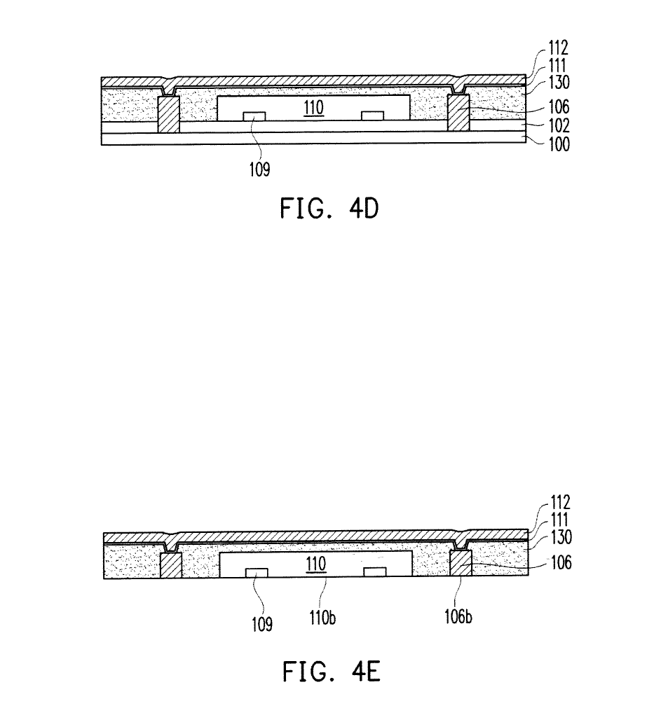

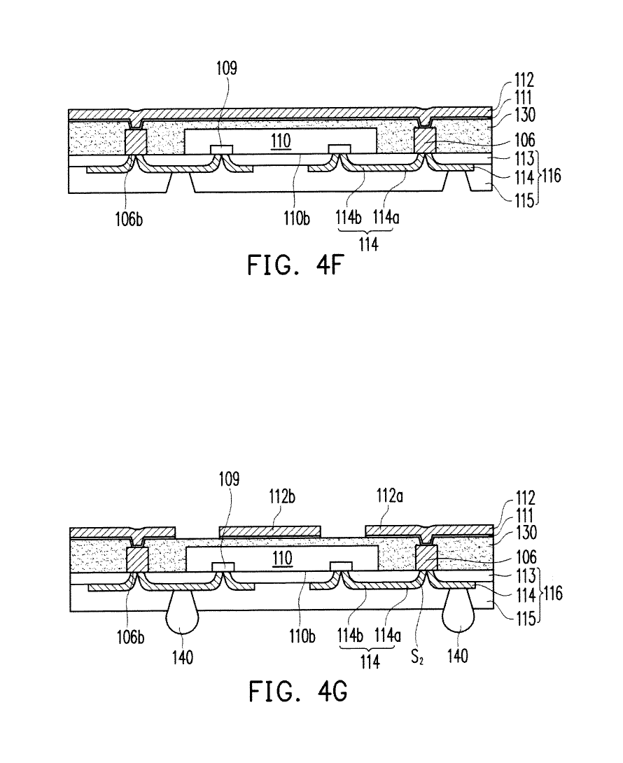

FIGS. 4A-4G illustrate a manufacturing process of a wafer level package structure according to another of the present embodiments. Referring to FIG. 4A, the sacrificial layer 100 includes the tape 102 and at least one die 110 disposed on the tape 102. After the photoresist layer 104 is formed on the die 110 and the tape 102, the plurality of openings S is formed in the tape 102 and the photoresist layer 104. The openings S may be formed by any of the processes described above. In general, the sacrificial layer 100 is attached to a rigid carrier 100C as described above, but the rigid carrier 100C is omitted from the figures for convenience.

Referring to FIG. 4B, the plurality of pillars 106 is formed within the openings S, and located on the sacrificial layer 100. Although the top surfaces 106a of the pillars 106 are illustrated in FIG. 4B as being coplanar with the top surface 110a of the die 110, the pillars 106 may be higher or lower than the die 110. The photoresist layer 104 is then removed.

Referring to FIG. 4C, the sacrificial layer 100 and the die 110 mounted thereon are overmolded with the molding compound 130 covering the die 110, the pillars 106, the tape 102, and the sacrificial layer 100. Then, the plurality of recesses S₁ is formed by removing portions of the molding compound 130 such that the upper surfaces 106a of the pillars 106 are exposed. The removal process may comprise any of the techniques described above. The recesses S, may have a constant diameter, or be cone shaped as shown, for example.

Referring to FIG. 4D, the seed layer 111 is applied to the upper surface of the molding compound 130, and into the recesses S₁ to cover the upper surfaces 106a of the pillars 106. Then, the conductive layer 112 is formed on the seed layer 111 and is electrically connected with the pillars 106. The conductive layer 112 conformally covers the molding compound 130, and the conductive layer 112 may partially or completely fill the recesses S₁. Since the aspect ratio of the recesses S₁ is small, the conductive layer 112 may completely fill the recesses S₁. Also, the conductive layer 112 covers the sidewalls of the recesses S₁ and is electrically connected to the pillars 106.

Referring to FIG. 4E, the sacrificial layer 100 at the bottom is etched off and a portion of the pillars 106 is etched until the bottom surface 106b of the metal pillar 106 is about co-planar with the bottom surface 110b of the die 110. Then, the tape 102 is removed to expose the pillars 106 and the contact pads 109 of the die 110.

Referring to FIG. 4F, a redistribution layer 116 is formed to cover the bottom surface 110b of the die 110 and the bottom surface 106b of the pillars 106. The illustrated redistribution layer 116 is multi-layered, and includes a first dielectric layer 113, a conductive layer 114 and a second dielectric layer 115. The conductive layer 114 is sandwiched between the dielectric layers 113, 115. The redistribution layer can help fan out the die pads to accommodate the fine pad pitch of the die, and is also interconnected to certain of the pillars 106. The formation of the redistribution layer 116 is preferably compatible with standard wafer level packaging processes and materials, and example processes are described below.

In one embodiment, after forming the dielectric layer 113 on the bottom of the reconstituted wafer, a via pattern for die pads and pillars is formed therein, and then the dielectric layer 113 is cured. The dielectric layer 113 may be formed by spin coating, or by any other process. The conductive layer 114 is the formed on the dielectric layer 113 and patterned into bottom interconnect portions 114a and bottom trace portions 114b. The bottom interconnect portions 114a and bottom trace portions 114b fan out the die pads 109 and interconnect pillars 106 with contact pads 109 as designed.

For example, at least one of the dielectric layers 113, 115 can be formed from polyimide, polybenzoxazole, benzocyclobutene, or a combination thereof, or any other material. The dielectric layers 113, 115 can be formed from the same dielectric material or different dielectric materials. In one embodiment, the bottom trace portion 114b is electrically connected to the contact pads 109. The bottom interconnect portions 114a may be electrically connected to the contact pads 109 and the pillars 106, or just the pillars 106. The bottom interconnect portions 114a may be used to fan out the die pads or to facilitate external connections.

Referring to FIG. 4G, electrical contacts 140 are formed within apertures S₂ of the second dielectric layer 115, and are connected to the bottom interconnect portions 114a of the conductive layer 114. The electrical contacts 140 may be solder balls, gold studs, or copper pillars, for example, or any other type of electrical contact. Moreover, the second dielectric layer 115 may have under bump metallization (UBM) formed therein for enhancing the cohesion of the electrical contacts 140. The conductive layer 112 is patterned into interconnect patterns 112a connecting to the pillars 106 and trace patterns 112b.

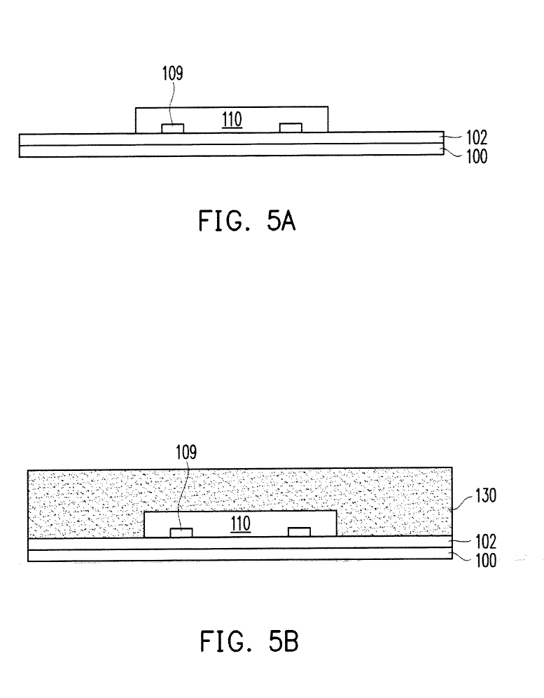

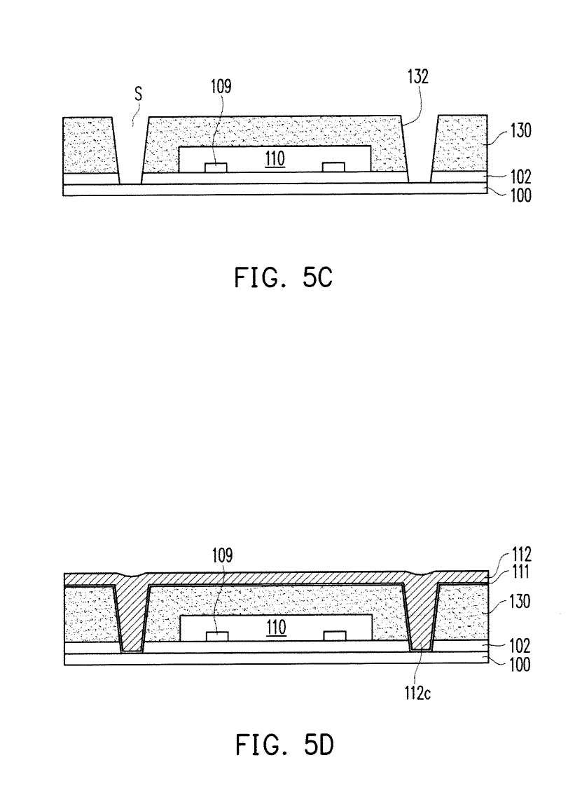

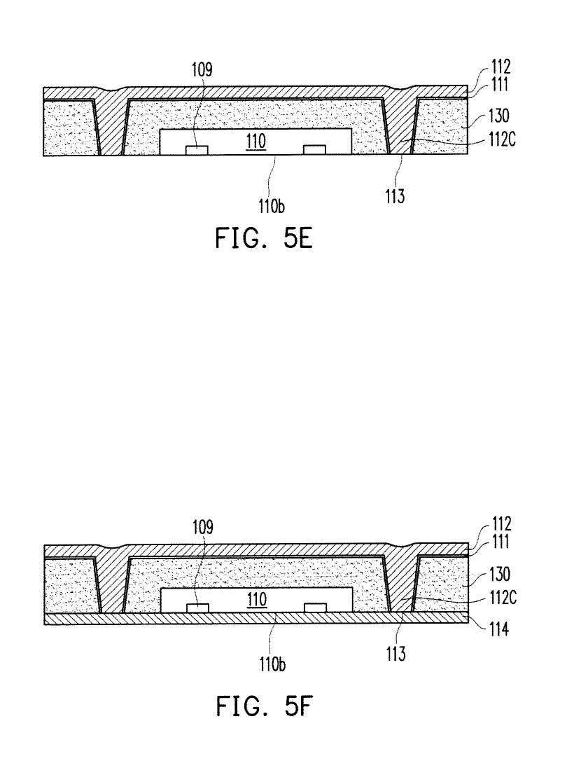

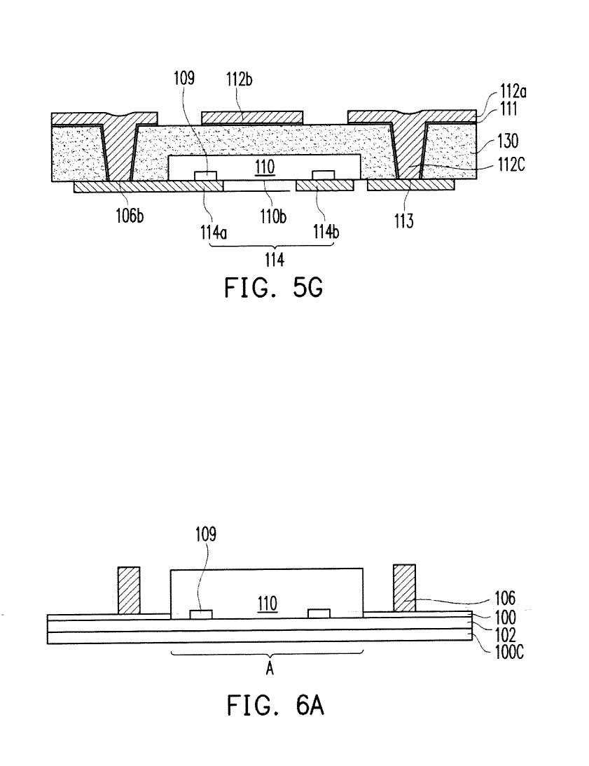

FIGS. 5A-5G illustrate a manufacturing process of a wafer level package structure according to another of the present embodiments. Referring to FIG. 5A, the sacrificial layer 100 having the tape 102 includes at least one die 110 disposed on the tape 102. In general, the sacrificial layer 100 is attached to a rigid carrier 100C as described above, but the rigid carrier 100C is omitted from the figures for convenience.

Referring to FIG. 5B, the sacrificial layer 100 and the die 110 mounted thereon are overmolded with the molding compound 130 covering the die 110, the tape 102 and the sacrificial layer 100.

Referring to FIG. 5C, the plurality of openings S is formed through the molding compound 130 using any of the processes described above. The openings S may have a uniform diameter or be tapered, or a combination of the two as shown, for example. If the openings S₁ are formed by laser drilling, surfaces 132 thereof will be rough due to particles in the molding compound 130 blocking the laser. Rough surfaces are often more difficult to plate than smooth surfaces. Thus, it is advantageous to form the pillars 106 first, and then form the molding compound 130 around the pillars, as in the processes of FIGS. 3A-3H and 4A-4G.

Referring to FIG. 5D, the seed layer 111 is applied to the upper surface of the molding compound 130, and into the openings S to coat the inner surfaces of the openings S. Any of the processes described above can be used to form the see layer 111. Then, the top conductive layer 112 is formed on the seed layer 111 by any of the processes described above. The conductive layer 112 covers the upper surface, the molding compound 130, and the conductive layer 112 may partially fill or completely fill the openings S. Since the aspect ratio of the openings S is small, the conductive layer 112 may completely fill the openings S. The portions of the conductive layer 112 within the openings S may thus be referred to as pillar portions 112c. Also, the conductive layer 112 preferably completely covers the sidewalls and the bottoms of the openings S. In this embodiment, the single step of forming the conductive layer 112 with pillar portions 112c replaces the separate steps of forming the pillars 106 and the conductive layer 112, as in the previous embodiments.

Referring to FIG. 5E, the sacrificial layer 100 at the bottom is removed and a portion of the conductive layer 112 within the openings S (pillar portions 112c) is removed from the bottom, until the bottom surfaces 113 of the pillar portions 112c are substantially co-planar with the bottom surface 110b of the die 110. The removal process may be according to any of the techniques described above. Then, the tape 102 is removed to expose the pillar portions 112c and the bottom surface 110b of the die 110.

Referring to FIG. 5F, the bottom conductive layer 114 is formed to cover the bottom surface 110b of the die 110 and the pillar portions 112c. The conductive layer 112 or the bottom conductive layer 114 may comprise any of the materials described above.

Referring to FIG. 5G, the conductive layer 112 is patterned to form a routing layer or trace patterns 112b on the upper surface of the package, as well as interconnect patterns 112a (including the pillar portions 112c). The bottom conductive layer 114 is patterned into bottom interconnect patterns 114a that are electrically connected to the pillar portions 112c and bottom trace patterns 114b.

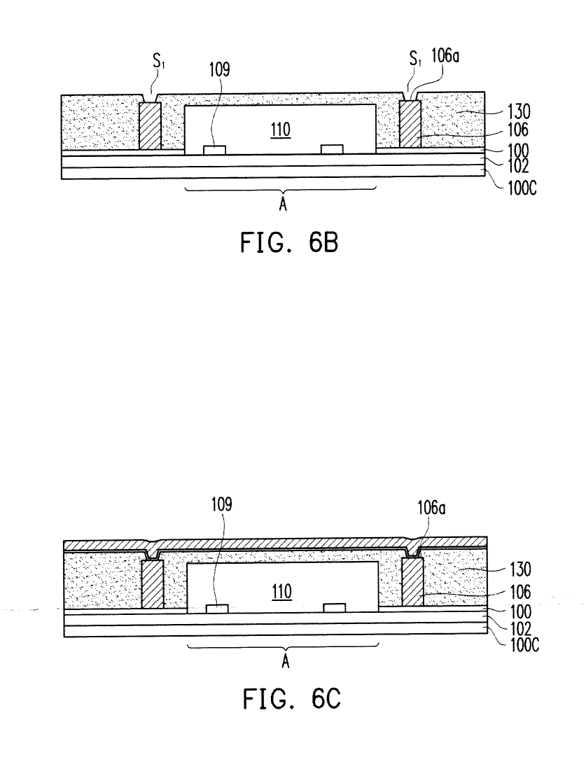

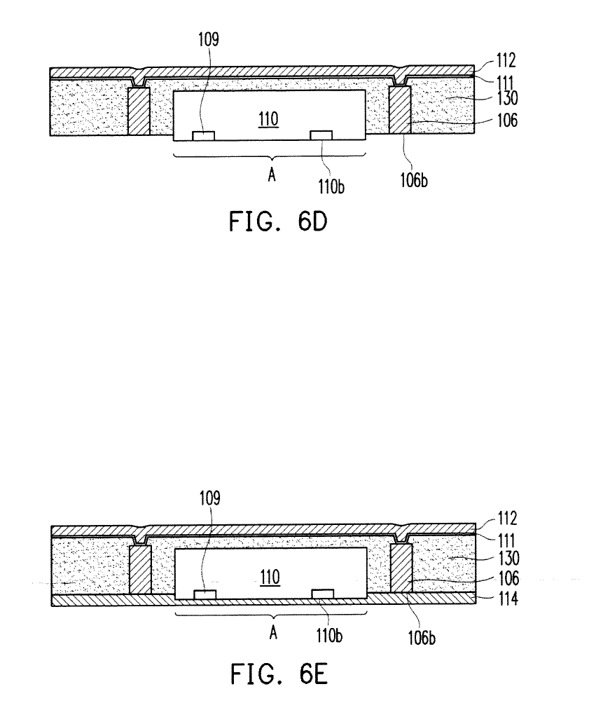

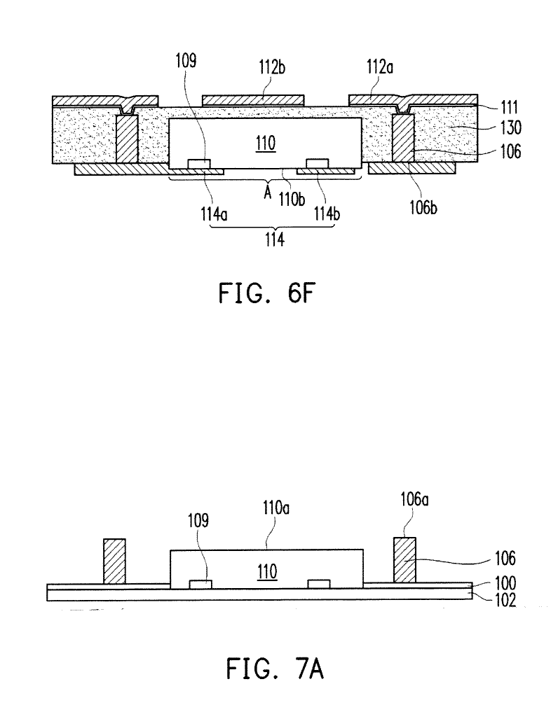

FIGS. 6A-6F illustrate a manufacturing process of a wafer level package structure according to another of the present embodiments. Referring to FIG. 6A, the sacrificial layer 100 having the plurality of pillars 106 formed thereon is attached to the rigid carrier 100C through the tape 102. The sacrificial layer 100 is removed to define a die-mounting area A. At least one die 110 is disposed in the die-mounting area A and on the tape 102. The die-mounting area may be defined by selectively etching, or by any other process.

Referring to FIG. 6B, the sacrificial layer 100 and the die 110 mounted thereon are overmolded with the molding compound 130 is covering the die 110, the pillars 106, the sacrificial layer 100 and over the tape 102. Then, the plurality of recesses S₁ is formed by removing portions of the molding compound 130 such that the upper surfaces 106a of the pillars 106 are exposed. The recesses S₁ may have a constant diameter or be tapered as shown, for example.

Referring to FIG. 6C, the seed layer 111 is applied to the upper surface of the molding compound 130 and into the recesses S₁ to cover the upper surfaces 106a of the metal pillars 106. Then, the conductive layer 112 is formed on the seed layer 111 and is electrically connected with the pillars 106. The seed layer 111 and the conductive layer 112 may be formed by any of the processes described above. The conductive layer 112 conformally covers the molding compound 130, and may partially or completely fill the recesses S₁. Since the aspect ratio of the recesses S₁ is small, the conductive layer 112 may completely fill the recesses S₁. Also, the conductive layer 112 preferably covers the sidewalls of the recesses S₁ and is electrically connected to the pillars 106.

Referring to FIG. 6D, the rigid carrier 100C and the tape 102 are removed. The sacrificial layer 100 at the bottom is removed and a portion of the pillars 106 may be removed. The removal processes may be according to any of the techniques described above. When the thickness of the sacrificial layer 100 is small, it is possible to overlook the height difference between the bottom surface 110b of the die and the bottom surface of the molding compound 130. The planarity mismatch between the bottom surface 110b of the die and the bottom surface of the molding compound 130 may not be drawn to scale.

Referring to FIG. 6E, the bottom conductive layer 114 is formed to cover the bottom surface 110b of the die 110 and the pillars 106.

Referring to FIG. 6F, the conductive layer 112 is patterned to form the routing layer or trace patterns 112b on the upper surface of the package as well as the interconnect patterns 112a connecting to the pillars 106. The bottom conductive layer 114 is patterned into the bottom interconnect patterns 114a that are connected to the pillars 106 and the bottom trace patterns 114b.

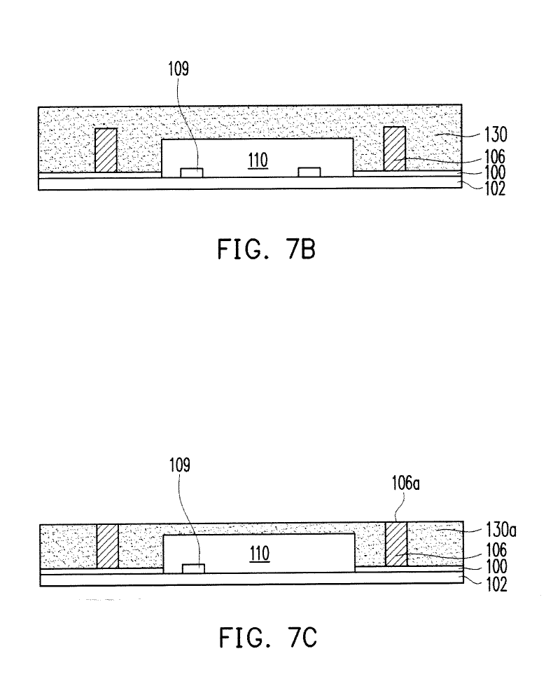

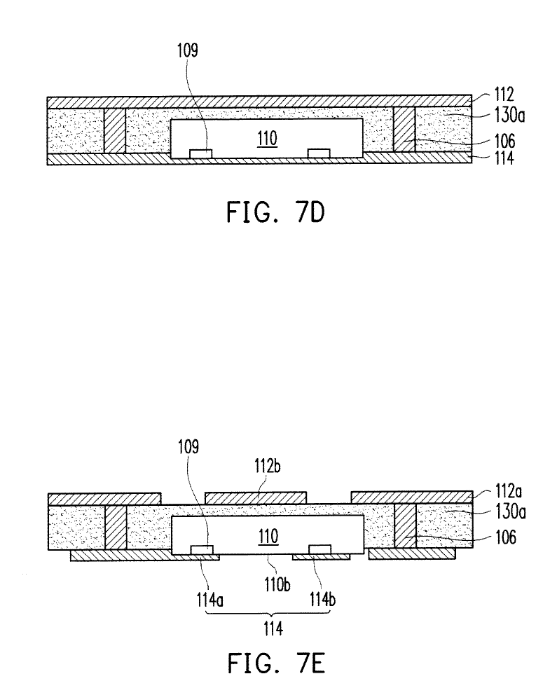

FIGS. 7A-7E illustrate a manufacturing process of a wafer level package structure according to another of the present embodiments. Referring to FIG. 7A, the sacrificial layer 100 having the plurality of pillars 106 formed thereon is disposed on the tape 102. The sacrificial layer 100 is removed to define the die-mounting area A and at least die 110 is disposed in the die-mounting area A and on the tape 102. The removal process may be according to any of the techniques described above. The tops 106a of the pillars 106 are higher than the top surface 110a of the die 110. In general, the sacrificial layer 100 is attached to the rigid carrier 100C as described above, but the rigid carrier 100C is omitted from the figures for convenience.

Referring to FIG. 7B, the sacrificial layer 100 and the die 110 mounted thereon overmolded so that the molding compound 130 covers the die 110, the pillars 106, the sacrificial layer 100 and the tape 102.

Referring to FIG. 7C, and upper portion of the molding compound 130 is removed to thin down the molding compound 130 until the upper surfaces 106a of the pillars 106 are exposed. The removal process may comprise grinding or any other process. The pillars 106 of this embodiment are in fact through-molding via plugs. The reduced thickness molding compound 130a is thicker than the die 110 to provide backside insulation between the die and the trace pattern to be formed thereon.

Referring to FIG. 7D, the tape 102 is removed to expose the sacrificial layer 100. The sacrificial layer 100 at the bottom is removed by any of the processes described above. Then, the top conductive layer 112 and the bottom conductive layer 114 are respectively formed to cover the top and bottom surfaces of the molding compound 130a.

Referring to FIG. 7E, the conductive layer 112 is patterned to form the routing layer or trace patterns 112b on the upper surface of the package as well as the interconnect patterns 112a connecting to the pillars 106. The bottom conductive layer 114 is patterned into the bottom interconnect patterns 114a that are connected to the pillars 106 and the bottom trace patterns 114b.

An anti-tarnish layer or a finish layer, such as a nickel/gold layer, organic solderabilty preservatives (OSP), electroless nickel-immersion gold (ENIG), or electroless nickel/electroless palladium/immersion gold (ENEPIG), may be formed over the upper and lower patterned metal layers 112, 114 to enhance additional connections. Solder mask may be selectively applied to protect the upper and lower patterned metal layers.

In another embodiment, the process of reducing the thickness of the molding compound 130 mentioned in connection with FIG. 7C may be performed such that the die 110's backside surface and upper portions of the pillars 106 are exposed from the molding compound 130a. In this embodiment, an additional dielectric coating (not shown) may be formed on the molding compound 130a as well as the die 110's exposed backside surface, but not on the pillars 106, and then the conductive layer 112 is formed on the dielectric coating as well as the pillars 106.

In alternate embodiments, a multi-layered redistribution layer may be employed, instead of the bottom metal patterns as described in the above embodiments, for farming out small pitch die pads or re-route dense traces.

From the above embodiments, the wafer level package structures can provide direct electrical connection for the devices to be mounted thereon or for the next level board. That is, the wafer level package structures can provide direct electrical connection for the devices or components mounted on both sides. The wafer level package structures of the present embodiments are suitable for 3-D wafer level packaging, and the stacked packages are compact in size. The wafer level package structure can be fabricated with routable patterns on both sides, which allows different packages or devices to be stacked together and improves design flexibility.

In the present embodiments, plating the pillars 106 in a dedicated plating step can advantageously be optimized for plating the pillars 106 without plating the upper surface of the mold compound 130/seed layer 111 using optimized plating chemistries and plating programs. By contrast, through mold via plating is more complex, because plating is preferentially in the via, but also to a lesser degree on the upper surface of the mold compound 130/seed layer 111. For that process, a different plating chemistry may be used and different plating programs. The plated surface may require a planarization process after to remove areas of over plating, i.e. non-uniformities. This process is also presents opportunities for defects to develop in the pillars 106, such as plating inclusions or voids.

While the foregoing discussion shows the redistribution layer (RDL) process on the bottom side of the package (die side), the RDL process can be applied to both sides to achieve the highest resolution of trace pitches. Further, while only a single layer RDL is shown, in alternative embodiments multiple stacked RDL layers can be provided as required by design.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not be necessarily being drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor device package, comprising:
a die having an active surface;
a molding compound partially encapsulating the die and having an upper surface;
a redistribution layer including at least one conductive layer and at least one dielectric layer, the redistribution layer formed partially on the active surface and partially on a lower surface of the molding compound;
a plurality of conductive pillars disposed in the molding compound and electrically connected to the redistribution layer;
a plurality of recesses in the upper surface of the molding compound, locations of the recesses corresponding to locations of the conductive pillars; and
a plurality of interconnect patterns electrically connected to the pillars, at least one of the interconnect patterns extending into at least one of the recesses.

2. The package of claim 1, further comprising a seed layer between the molding compound and the interconnect patterns.

3. The package of claim 1, wherein the recesses are conical.

4. The package of claim 3, wherein the recesses have a larger diameter at a location spaced from the pillars and a smaller diameter adjacent the pillars.

5. The package of claim 1, wherein the molding compound overlaps edges of upper surfaces of the pillars.

6. The package of claim 1, wherein the redistribution layer includes a conductive layer between an upper dielectric layer and a lower dielectric layer.

7. The package of claim 1, wherein the semiconductor device package is a first semiconductor device package, and further comprising a second semiconductor device package stacked on the first semiconductor device package.

8. A semiconductor device package, comprising:
a die having an active surface;
a molding compound partially encapsulating the die and having an upper surface;
a redistribution layer including at least one conductive layer and at least one dielectric layer, the redistribution layer formed partially on the active surface and partially on a lower surface of the molding compound;
a plurality of conductive pillars disposed in the molding compound and electrically connected to the redistribution layer; and
a plurality of recesses in the upper surface of the molding compound, locations of the recesses corresponding to locations of the conductive pillars and exposing at least a portion of upper surfaces of the pillars;
wherein the molding compound overlaps edges of the upper surfaces of the pillars.

9. The package of claim 8, further comprising a plurality of interconnect patterns on the molding compound and the pillars, the interconnect patterns at least partially filling the recesses in the molding compound.

10. The package of claim 9, further comprising a seed layer between the molding compound and the interconnect patterns.

11. The package of claim 8, wherein the recesses are conical.

12. The package of claim 11, wherein the recesses have a larger diameter at a location spaced from the pillars and a smaller diameter adjacent the pillars.

13. The package of claim 8, wherein the redistribution layer includes a conductive layer between an upper dielectric layer and a lower dielectric layer.

14. The package of claim 8, wherein the semiconductor device package is a first semiconductor device package, and further comprising a second semiconductor device package stacked on the first semiconductor device package.

15. A method of making a semiconductor device package, the method comprising:
forming a plurality of conductive pillars on a sacrificial layer;
placing at least one die on the sacrificial layer;
forming a molding compound on the sacrificial layer and encapsulating the at least one die and at least the partially encapsulating the pillars;
forming a plurality of recesses in the molding compound adjacent upper surfaces of the pillars;
forming a plurality of interconnect patterns on the molding compound and the pillars, the interconnect patterns at least partially filling the recesses in the molding compound;
removing the sacrificial layer; and
forming a redistribution layer on the die, the pillars and the molding compound, the redistribution layer including at least one conductive layer and at least one dielectric layer.

16. The method of claim 15, wherein forming the plurality of the recesses comprises laser drilling.

17. The method of claim 15, further comprising forming a seed layer over the molding compound and at least partially filling the recesses.

18. The method of claim 15, wherein the recesses are conical.

19. The method of claim 18, wherein the recesses have a larger diameter at a location spaced from the pillars and a smaller diameter adjacent the pillars.

20. The method of claim 15, wherein the redistribution layer includes a conductive layer sandwiched between an upper dielectric layer and a lower dielectric layer.
